(19) United States
(12) Patent Application Publication
(10) Pub. No.: US 2012/0073957 A1
(43) Pub. Date: Mar. 29, 2012

(54) USE OF A PROCESS FOR DEPOSITION BY SPUTTERING OF A CHALCOGENIDE LAYER

(76) Inventor: Faiz Dahmani, La Varenne-Saint Hilaire (FR)

(21) Appl. No.: 13/246,078

(22) Filed: Sep. 27, 2011

(30) Foreign Application Priority Data
Apr. 10, 2010 (FR) 1058009

(51) Int. Cl. C23C 14/34; C23C 14/06

(52) U.S. Cl. 204/192.1

(57) ABSTRACT

A deposition process includes sputtering of a layer of a material having a chalcogenide compound, the chalcogenide being composed of at least one chalcogen on and at least one electropositive element, in order to increase or to decrease the atomic proportion (%) of the chalcogen ion with respect to the atomic proportion (%) of the electropositive element.

### RELATED APPLICATION

This application claims the benefit of priority from French Patent Application No. 10 58009, filed on Apr. 10, 2010, the entirety of which is incorporated by reference.

### BACKGROUND

1. Field of the Invention

The present invention relates to the use of a process for deposition by sputtering of a chalcogenide layer in order to increase the atomic fraction (%) of the chalcogen ion forming the chalcogenide compound.

2. Description of the Related Art

It is typically, but not exclusively, applicable to the fabrication of microelectronic devices with a programmable memory, and notably to the fabrication of programmable ion-conduction cells (metallization cells), which are computer memories referred to as “non-volatile memories”. These programmable ion-conduction cells are known by the term CBRAM, for “Conductive-Bridging Random Access Memory”, or PMC, for “Programmable Metallization Cell”.

This type of microelectronic structure (CBRAM or PMC) is for example described in the document U.S. Pat. No. 6,084,796.

A CBRAM (or PMC) typically comprises a layer (or solid electrolyte) of a chalcogenide glass doped with a metal element, preferably silver, sandwiched between two electrodes. These electrodes are configured to make a metal dendrite grow (i.e. formation of an electrical conduction bridge) from the negative of the two electrodes towards the positive of the two electrodes through the layer of doped chalcogenide glass when a voltage is applied between the said electrodes. By applying an opposing voltage between these two electrodes, the inverse phenomenon is obtained, namely the disappearance of the metal dendrite (i.e. disappearance of the electrical conduction bridge) within the layer of doped chalcogenide glass.

Thus, when the electrical conduction bridge is created (step referred to as “writing step”), the logic state of the device can be represented by “1”, or can correspond to the “ON” state, whereas when the electrical conduction bridge disappears, the logic state of the cell can be represented by “0”, or can correspond to the “OFF” state.

The stoichiometry of the chalcogenide compound, or in other words the atomic percentage of the various elements composing the chalcogenide compound, is an essential factor in obtaining optimum electrical performance characteristics in the programmable ion-conduction cells.

For example, considering a germanium sulphide chalcogenide compound, with formula GeₓS₁₀₀₋ₓ, in which x is an integer number, the greater the proportion of sulphur with respect to germanium, the better are notably the electrical performance characteristics of the programmable cells formed from this chalcogenide compound.

In the following publications: M. Mitkova, M. N. Kozicki “Ag-photodoping in Ge-chalcogenide amorphous thin films—Reaction products and their characterization”, Journal of Physics and Chemistry of Solids 68, 866 (2007); M. Balakrishnan et al., “Crystallization effects in annealed thin GeS₂ films photodiffused with Ag”, Journal of Non-Crystalline Solids 353, 1454 (2007), an optimum stoichiometry of germanium sulphide material has been defined, namely that of Ge₃₃S₆₇ (or GeS₂).

This particular stoichiometry features several advantages. It allows the thermal stability of the chalcogenide to be improved, and the solubility point of the metal element dopant in the chalcogenide compound to be raised during the fabrication of the said programmable cells, and thus allows the electrical performance characteristics of the said cells to be improved.

The conventional techniques for formation of a chalcogenide layer typically consist in using the technique of deposition by sputtering. Sputtering is a method for thin-film deposition, which is a technique permitting the synthesis of at least one material based on the condensation of a metal vapour coming from a solid source (i.e. a target) onto a substrate positioned on a sample holder. The substrate, preferably a semi-conductor, is well known to those skilled in the art and can for example be chosen from amongst silicon, silicon oxide, and quartz substrates.

More particularly, sputtering thus allows a layer of a chalcogenide material, whose stoichiometry is identical to that of the target, to be formed starting from a target of a chalcogenide. material of given stoichiometry, and by means of an argon plasma. The stoichiometry of the layer obtained is not therefore modified with respect to that of the target.

Certain other techniques can allow the atomic proportion in sulphur of a germanium sulphide chalcogenide to be increased. In this respect, the document entitled “Oxygen-assisted photoinduced structural transformation in amorphous Ge—S films”, by Y. Sakaguchi, D. A. Tenne, M. Mitkova—Phys. Status Solidi B 246, No, 8, 1813-1819 (2009), may be mentioned. This document describes the vacuum deposition of a layer of germanium sulphide with the formula Ge₄₆S₅₄. The deposited film is then irradiated in air by a continuous laser beam of wavelength 441 nm with a power of 80 mW. After an irradiation of 21 minutes, a film of Ge₃₃S₆₆ (i.e. GeS₂) was obtained. The laser irradiation in air promotes the oxidation of germanium and hence the depletion of the Ge₄₆S₅₄ into germanium by the formation of GeO₂ at the surface of the film. This leads to a reduction in the Ge/S ratio (ratio in atomic fraction (%)) in germanium sulphide film.

### OBJECTS AND SUMMARY

However, the use of a laser does not allow this technique to be generalized to the entire surface of the deposited film, but limits the area of the deposition to the region defined by the area of application of the laser beam. Moreover, the irradiation time is relatively long in order to obtain this structural change within the film.

For this reason, the process of the prior art, designed to increase the proportion of the chalcogen ion S within the chalcogenide compound, is not optimized, and renders the fabrication of the chalcogenide layer complex, costly and maladapted to a fabrication process of the industrial type.

The aim of the present invention is to overcome the drawbacks of the techniques of the prior art by notably providing a novel use of a process allowing the increase (or the decrease) in the atomic proportion (%) of the chalcogen ion in a chalcogenide compound to be significantly optimized and at lower cost.

The subject of the present invention is the use of a deposition process by sputtering of a layer of a material comprising a chalcogenide compound, the chalcogenide being composed of at least one chalcogen ion and at least one electropositive element, in order to increase or to decrease the atomic proportion (%) of the chalcogen on with respect to the atomic proportion (%) of the electropositive element.

More particularly, the layer deposited by the deposition process by sputtering is formed starting from a source material (i.e. a target), notably solid, comprising a chalcogenide compound of a given stoichiometry, the stoichiometry of the chalcogenide in the said deposited layer being different from that of the chalcogenide of the source material.

In other words, the stoichiometry of the chalcogenide composing the material of the layer deposited according to the invention is therefore modified with respect to that of the chalcogenide composing the source material.

The Applicant has discovered that, surprisingly, the increase, or the decrease, of the atomic proportion of the chalcogen ion can respectively be a function of the decrease, or of the increase, of the power density during the sputter deposition.

Thus, by decreasing the power density needed for the formation (i.e. deposition) of the said layer by sputtering, the atomic proportion (%) of the chalcogen ion in the material comprising the chalcogenide compound advantageously increases in an optimal manner.

The advantage of having a chalcogenide compound with a ratio of the atomic proportion (%) of the electropositive element over the atomic proportion (%) of the chalcogen ion that is as low as possible, or in other words the atomic proportion (%) of the chalcogen ion as high as possible, is that it allows the thermal stability of the chalcogenide to be improved, and its electrical performance characteristics to be increased, notably when it is used in microelectronic devices with a programmable memory.

According to the invention, the material forming the layer comprises a chalcogenide composed of at least one chalcogen ion and at least one electropositive element.

This material is preferably a chalcogenide compound as such. In this case, the layer could be described as a layer of a chalcogenide material or as a chalcogenide layer.

More particularly, this material can be a chalcogenide glass. In this case, the layer could be described as a layer of a chalcogenide glass material or as a chalcogenide glass layer.

A chalcogenide may be represented by the following formula: Aₓ₁B₁₀₀₋ₓ₁, in which A is an electropositive element, B a chalcogen ion, and x1 an integer number in the range from 1 to 99.

Thus, in order to illustrate the actual principle of the invention, the use of the deposition process by sputtering allows a chalcogenide represented for example by the following formula to be obtained: Aₓ₂B₁₀₀₋ₓ₂, in which A and B are such as previously defined, and x2 an integer number in the range between 1 and 99, x2 being less than x1.

The chalcogens, comprising the chalcogen ions, are conventionally grouped in group 16 of the periodic table of the elements, and those preferably used in the invention are sulphur (5), selenium (Se) and tellurium (Te).

The electropositive element forming the chalcogenide compound can more particularly be:
an element of group 14 (i.e. group IVA) of the periodic table of the elements, such as notably silicon (Si) or germanium (Ge), or
an element of group 15 (i.e. group VA) of the periodic table of the elements, such as notably phosphorus (P), arsenic (As), antimony (Sb) or bismuth (Bi).

Preferably, the said electropositive element is germanium (Ge) or arsenic (As).

The material is typically referred to as chalcogenide glass when the electropositive element of the chalcogenide compound belongs to group 14 or to group 15 of the periodic table of the elements.

By way of example of a chalcogenide, germanium selenide GeₓSe₁₀₀₋ₓ, germanium sulphide GeₓS₁₀₀₋ₓ, or arsenic sulphide AsₓS₁₀₀₋ₓ may be mentioned, x being an integer number in the range from 1 to 99.

The preferred chalcogenide is germanium sulphide GeₓS₁₀₀₋ₓ.

The sputtering is notably carried out in the presence of a noble gas so as to form a plasma of the said noble gas. Preferably, the noble gas is argon so as to form an argon plasma.

The deposition of the layer of the material comprising a chalcogenide can be advantageously carried out with a radiofrequency (RF) power density of, at the most, 0.60 W/cm², preferably of, at the most, 0.23 W/cm², and most preferably of, at the most, 0.21 W/cm².

For the process of deposition by sputtering, a plasma needs to be formed that is stable throughout the duration of the deposition process. In this respect, it is preferable for the power density (RF) to be at least 0.023 W/cm². Moreover, at a power density (RF) of less than 0.21 W/cm², the deposition rate is relatively slow.

By way of example, the power density (RF) used is around 0.060 W/cm².

According to another embodiment, the deposition of the layer of the material comprising a chalcogenide could equally well be carried out with a power density being applied, not as a radiofrequency voltage, but as a pulsed DC voltage.

Another condition for forming a stable noble gas plasma is that the deposition process be carried out under a high enough gas pressure. By way of example, a pressure seen as sufficient can be of at least 1 mTorr (0.13 Pa).

When the pressure is too high, on the one hand, the uniformity of the layer formed may be degraded and, on the other hand, its density may be affected. Preferably, the deposition pressure can be, at the most, equal to 7 mTorr (0.93 Pa), and preferably equal to a maximum of 6 mTorr (0.79 Pa).

In one particular embodiment, the layer according to the invention is formed at a deposition temperature that is lower than the sublimation temperature of the chalcogen.

By way of example, when the chalcogen in question is sulphur, since the sublimation temperature of the sulphur is around 120° C., this deposition temperature is below 120° C., and preferably lower than 40° C.

This notwithstanding, the Applicant has noticed that, surprisingly, the increase, or the decrease, of the atomic proportion of the chalcogen ion can respectively be a function of the decrease, or of the increase, in the temperature during the deposition of the layer by sputtering, irrespective of the power density applied.

Thus, by decreasing the temperature during the deposition of the layer by sputtering, the atomic proportion (%) of the chalcogen ion in the material comprising the chalcogenide compound advantageously increases in an optimal manner.

More particularly, the deposition of the layer by sputtering is carried out at a temperature below 0° C., and preferably at a temperature below −10° C.

In order to optimize the deposition of the layer of the material comprising a chalcogenide compound, those skilled in the art will advantageously be able to associate the decrease in power with the decrease in temperature.

Albeit less straightforwardly, they will also be able to associate the increase in power with the increase in temperature, or else combine the decrease in power with the increase in temperature, or else combine the increase in power with the decrease in temperature.

Furthermore, a step referred to as thermal treatment may be carried out following the deposition of the layer of chalcogenide material. In order to avoid any level of oxidation of the layer, this step is carried out in an atmosphere substantially free from oxygen, and preferably under vacuum.

This thermal treatment is designed to eliminate at least a part of the contaminants of the said layer. These contaminants may originate from within the target and thus are likely to be present during the deposition of the said layer. These contaminants can generally induce electrical problems when the layer is used in microelectronic devices with a programmable memory. By way of example, these contaminants may be the element hydrogen.

It is of course also necessary for this thermal treatment step to be carried out at a deposition temperature that is lower than the sublimation temperature of the chalcogen.

By way of example, this thermal treatment temperature is higher than 50° C.

When the chalcogen in question is sulphur, the thermal treatment temperature can be in the range from 50 to 100° C. More particularly, thermal treatment will be applied for 5 to 30 minutes at a temperature that can be from 50 to 100° C. The optimum thermal treatment corresponds to a treatment of 15 minutes at 90° C.

Once the layer of material according to the invention has been prepared, it is of course typically doped with a metal element, using techniques well known to those skilled in the art in order to incorporate it, for example, into programmable ion-conduction devices (CBRAM or MPC).

The temperatures mentioned in the present invention correspond more precisely to the temperatures of the sample holder onto which the layer according to the invention is deposited, this deposition being conventionally carried out onto a substrate sandwiched between the sample holder and the said layer.

### BRIEF DESCRIPTION OF THE DRAWINGS

Other features and advantages of the present invention will become apparent in the light of the examples presented below with reference to the single annotated FIGURE, the said examples and FIGURE being wholly non-limiting and presented by way of illustration.

FIG. 1 shows the variation of the atomic percentage of sulphur and of germanium in a layer of a chalcogenide glass GeₓS₁₀₀₋ₓ as a function of the applied power, the said layer being formed by sputtering from a target of Ge₄₂S₅₈ being 13 inches (33 cm) in diameter,

### DETAILED DESCRIPTION

### Examples

In order to form a layer of chalcogenide glass GeₓS₁₀₀₋ₓ according to the invention, a target of Ge₄₂S₅₈ being 13 inches (33 cm) in diameter is bombarded by forming an argon plasma with variable radiofrequency powers going from 500 W to 50 W (respectively equivalent to around 0.60 W/cm² and 0.060 W/cm² in power density).

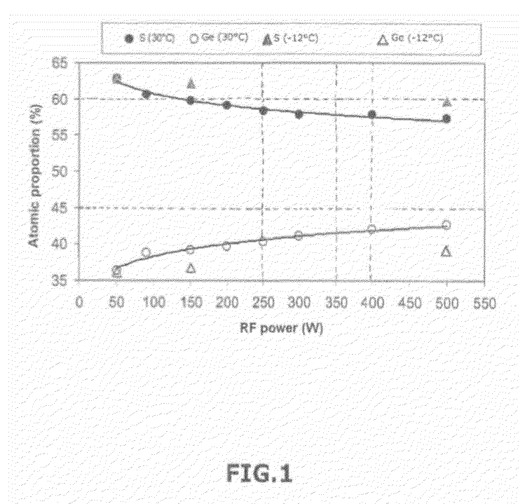

FIG. 1 shows the variation of the atomic percentage of sulphur and of germanium in a chalcogenide layer GeₓS₁₀₀₋ₓ as a function of the power applied during the sputtering.

The values of atomic percentage (i.e. stoichiometry) for the elements S and Ge are obtained by SEM-EDX (for Scanning Electron Microscope-Energy Dispersive X ray spectroscopy). The measurements are carried out by means of an instrument of the Hitachi F2360N type with a beam of energy 7 keV in a secondary vacuum of 1.33 Pa, at room temperature.

According to a first experiment, the deposition of the chalcogenide layer is carried out at a temperature (i.e. temperature of the sample holder) of around 30° C. FIG. 1 allows the variation of the stoichiometry of the layer GeₓS₁₀₀₋ₓ thus formed to be clearly shown, in which x is, in this case, an integer number less than 42: the lower the power, the closer the composition of the layer of GeₓS₁₀₀₋ₓ approaches that of GeS₂.

For example, it is observed that with a power of 50 W, a layer of Ge₃₆S₆₄ is obtained.

According to a second experiment, the deposition of the chalcogenide layer is carried out at a temperature (i.e. temperature of the sample holder) of around −12° C. FIG. 1 also allows the variation of the stoichiometry of the layer GeₓS₁₀₀₋ₓ thus formed to be shown. It will be noticed that, for a given power, the atomic proportion (%) of sulphur (S) increases to a higher level at −12° C. than at 30° C.

Indeed,
at 500 W (RF), the atomic proportion (%) of sulphur is 57.2 at 30° C., whereas it is 59.7 at −12° C.; and
at 150 W (RF), the atomic proportion (%) of sulphur is 59.7 at 30° C., whereas it is 62.1 at −12° C.

1. A method for a deposition process comprising:
sputtering of a layer of a material comprising a chalcogenide compound, wherein the chalcogenide is composed of at least one chalcogen on and at least one electropositive element, in order to increase or to decrease the atomic proportion (%) of the chalcogen ion with respect to the atomic proportion (%) of the electropositive element.

2. The method according to claim 1, wherein the layer deposited by the said deposition process is formed starting from a source material comprising a chalcogenide compound of a given stoichiometry, the stoichiometry of the chalcogenide in the said deposited layer being different from that of the chalcogenide of the source material.

3. The method according to claim 1, wherein the increase, or the decrease, in the atomic proportion of the chalcogen ion is respectively a function of the decrease, or of the increase, in the power density during the sputter deposition.

4. The method according to claim 1, wherein the deposition of the layer by sputtering is carried out with a radiofrequency power density of, at the most, 0.6 W/cm².

5. The method according to claim 1, wherein the increase, or the decrease, in the atomic proportion of the chalcogen ion is respectively a function of the decrease, or of the increase, in the temperature during the sputter deposition.

6. The method according to claim 1, wherein the deposition of the layer by sputtering is carried out at a deposition temperature lower than the sublimation temperature of the chalcogen.

7. The method according to claim 6, wherein the deposition of the layer by sputtering is carried out at a temperature below 0° C.

8. The method according to claim 1, wherein, once the layer has been sputter deposited, it undergoes a thermal treatment step designed to eliminate at least a part of the contaminants from the said layer.

9. The method according to claim 1, wherein the chalcogen ion is selected from the group consisting of sulphur (S), selenium (Se), and tellurium (Te).

10. The method according to claim 1, wherein the electropositive element is germanium (Ge) or arsenic (As).

11. The method according to claim 1, wherein the layer is formed under a deposition pressure of, at most, 7 mTorr (0.93 Pa).

12. The method according to claim 1, wherein the deposition process is carried out by means of a noble gas plasma.

13. A method for the fabrication of a microelectronic device with a programmable memory, said method comprising the step of a deposition process according to claim 1.

14. The method according to claim 4, wherein the deposition of the layer by sputtering is carried out with a radiofrequency power density of, at the most, 0.23 W/cm².

15. The method according to claim 12, wherein the deposition process is carried out by means of an argon plasma.
